(19) United States
(12) Patent Application Publication
(10) Pub. No.: US 2023/0387286 A1
(43) Pub. Date: Nov. 30, 2023

(54) NITRIDE SEMICONDUCTOR DEVICE

(71) Applicant: Panasonic Holdings Corporation, Osaka (JP)

(72) Inventors: Daisuke SHIBATA, Kyoto (JP); Satoshi TAMURA, Osaka (JP); Manabu YANAGIHARA, Osaka (JP)

(21) Appl. No.: 18/446,284

(22) Filed: Aug. 8, 2023

Related U.S. Application Data
(63) Continuation of application No. PCT/JP2022/000941, filed on Jan. 13, 2022.

(30) Foreign Application Priority Data
Feb. 16, 2021 (JP) 2021-022353

(51) Int. Cl. H01L 29/778; H01L 29/20; H01L 29/40

(52) U.S. Cl. CPC H01L 29/7786; H01L 29/2003; H01L 29/402

(57) ABSTRACT

A nitride semiconductor device includes: a substrate; a first semiconductor layer disposed above the substrate; a second semiconductor layer disposed above the first semiconductor layer; a third semiconductor layer disposed above the second semiconductor layer; a first opening which penetrates through the third semiconductor layer and the second semiconductor layer to reach the first semiconductor layer; a semiconductor multilayer including a channel region; a fourth semiconductor layer disposed along the upper surface of the semiconductor multilayer; a gate electrode; a source electrode; a drain electrode; and a groove which is provided at an end portion of the nitride semiconductor device and penetrates through the second semiconductor layer to reach the first semiconductor layer, and a distance between the bottom of the first opening and the substrate is shorter than a distance between the bottom of the groove and the substrate.

### CROSS REFERENCE TO RELATED APPLICATIONS

This is a continuation application of PCT International Application No. PCT/JP2022/000941 filed on Jan. 13, 2022, designating the United States of America, which is based on and claims priority of Japanese Patent Application No. 2021-022353 filed on Feb. 16, 2021. The entire disclosures of the above-identified applications, including the specifications, drawings and claims are incorporated herein by reference in their entirety.

### FIELD

The present disclosure relates to nitride semiconductor devices.

### BACKGROUND

Nitride semiconductors such as gallium nitride (GaN) are wide-gap semiconductors with a large band gap, have a high dielectric breakdown electric field strength, and have a higher saturated drift velocity of electrons than gallium arsenide (GaAs) semiconductors or silicon (Si) semiconductors. Hence, research and development of power transistors using nitride semiconductors which are advantageous for high output and high voltage resistance are conducted.

For example, Patent Literature (PTL) 1 discloses a vertical field effect transistor (FET) including: a regrown layer which is located to cover an opening provided in a GaN-based multilayer; and a gate electrode which is located on the regrown layer along the regrown layer. A channel is formed by a 2-dimensional electron gas (2DEG) generated in the regrown layer.

For example, PTL 2 discloses a semiconductor device which includes an isolation trench for separating the semiconductor device from other devices.

### CITATION LIST

### Patent Literature

PTL 1: International Publication No. 2020/137303
PTL 2: Japanese Unexamined Patent Application Publication No. 2014-236089

### SUMMARY

### Technical Problem

There is room for improvement in the off characteristics of the conventional semiconductor devices described above.

The present disclosure provides a nitride semiconductor device in which off characteristics are improved.

### Solution to Problem

A nitride semiconductor device according to an aspect of the present disclosure includes: a substrate; a first semiconductor layer of a first conductivity type which is disposed above the substrate; a second semiconductor layer of a second conductivity type which is disposed above the first semiconductor layer; a third semiconductor layer which is disposed above the second semiconductor layer; a first opening which penetrates through the third semiconductor layer and the second semiconductor layer to reach the first semiconductor layer; a semiconductor multilayer having one portion disposed along an inner surface of the first opening and the other portion disposed above the third semiconductor layer and including a channel region of the first conductivity type; a fourth semiconductor layer of the second conductivity type which is disposed along an upper surface of the semiconductor multilayer; a gate electrode which is disposed above the fourth semiconductor layer; a source electrode which is disposed away from the gate electrode; a drain electrode which is disposed on a side of a lower surface of the substrate; and a groove which is provided at an end portion of the nitride semiconductor device and penetrates through the second semiconductor layer to reach the first semiconductor layer, and a distance between a bottom of the first opening and the substrate is shorter than a distance between a bottom of the groove and the substrate.

### Advantageous Effects

According to the present disclosure, it is possible to provide a nitride semiconductor device in which off characteristics are improved.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a nitride semiconductor device according to Embodiment 1.

FIG. 2 is a plan view of the nitride semiconductor device according to Embodiment 1.

FIG. 3 is a cross-sectional view of a nitride semiconductor device according to Embodiment 2.

FIG. 4 is a cross-sectional view of a nitride semiconductor device according to Embodiment 3.

FIG. 5 is a cross-sectional view of a nitride semiconductor device according to Embodiment 4.

FIG. 6 is a cross-sectional view of a nitride semiconductor device according to a variation of Embodiment 4.

FIG. 7 is a cross-sectional view of a nitride semiconductor device according to Embodiment 5.

FIG. 8 is a cross-sectional view of a nitride semiconductor device according to Variation 1 of Embodiment 5.

FIG. 9 is a cross-sectional view of a nitride semiconductor device according to Variation 2 of Embodiment 5.

FIG. 10 is a plan view of a nitride semiconductor device according to Variation 2 of Embodiment 5.

### DESCRIPTION OF EMBODIMENTS

### (Underlying Knowledge Forming Basis of the Present Disclosure)

The present inventors have found that the following problems occur in the conventional semiconductor devices described in “Background”.

The isolation trench disclosed in PTL 2 is formed by dry etching. In the vicinity of the isolation trench, deterioration of film quality easily occurs due to damage caused by dry etching.

When an FET is off, a high voltage is applied between a drain and a source. When an isolation trench is provided as in the semiconductor device disclosed in PTL 2, electric field concentration easily occurs in the isolation trench in the off state. When electric field concentration occurs in the isolation trench, deterioration of film quality in the vicinity of the isolation trench may cause an increase in leakage current or a decrease in voltage resistance in the off state. In other words, the off characteristics of the semiconductor device deteriorate.

Hence, the present disclosure provides a nitride semiconductor device in which off characteristics are improved. Specifically, the present disclosure provides a nitride semiconductor device which can reduce a leakage current and suppress a decrease in voltage resistance in an off state.

A nitride semiconductor device according to an aspect of the present disclosure includes: a substrate; a first semiconductor layer of a first conductivity type which is disposed above the substrate; a second semiconductor layer of a second conductivity type which is disposed above the first semiconductor layer; a third semiconductor layer which is disposed above the second semiconductor layer; a first opening which penetrates through the third semiconductor layer and the second semiconductor layer to reach the first semiconductor layer; a semiconductor multilayer having one portion disposed along an inner surface of the first opening and the other portion disposed above the third semiconductor layer and including a channel region of the first conductivity type; a fourth semiconductor layer of the second conductivity type which is disposed along an upper surface of the semiconductor multilayer; a gate electrode which is disposed above the fourth semiconductor layer; a source electrode which is disposed away from the gate electrode; a drain electrode which is disposed on a side of a lower surface of the substrate; and a groove which is provided at an end portion of the nitride semiconductor device and penetrates through the second semiconductor layer to reach the first semiconductor layer, and a distance between a bottom of the first opening and the substrate is shorter than a distance between a bottom of the groove and the substrate.

In this way, in the first opening, the pn junction of the semiconductor multilayer and the fourth semiconductor layer is present. Since the fourth semiconductor layer can be continuously formed from the semiconductor multilayer, the pn junction described above has a higher quality and a higher electric field strength than a pn junction subjected to etching damage in the vicinity of the groove.

In the nitride semiconductor device according to the present aspect, the bottom of the first opening is closer to the substrate than the bottom of the groove, and thus an electric field caused by a voltage applied between a drain and a source in an off state is more likely to be concentrated on the first opening than on the groove. Hence, electric field concentration can be received by the pn junction of a high quality, and thus it is possible to relax electric field concentration on the pn junction in the vicinity of the groove. In this way, it is possible to improve the off characteristics of the nitride semiconductor device. Specifically, it is possible to reduce a leakage current in the vicinity of the groove and to suppress a decrease in voltage resistance.

For example, a distance between a bottom of the fourth semiconductor layer in the first opening and the substrate may be shorter than the distance between the bottom of the groove and the substrate.

In this way, the pn junction in the first opening is closer to the substrate than the pn junction in the vicinity of the groove, and thus electric field concentration can be received by the pn junction in the first opening. Hence, it is possible to improve the off characteristics of the nitride semiconductor device.

For example, the nitride semiconductor device according to the aspect of the present embodiment may further include: a second opening which is provided away from the gate electrode and penetrates through the semiconductor multilayer and the third semiconductor layer to reach the second semiconductor layer, and the source electrode may be provided along an inner surface of the second opening.

In this way, a channel region included in the semiconductor multilayer and the source electrode are in direct contact with each other, and thus it is possible to reduce the contact resistance of the channel region and the source electrode. Since the second semiconductor layer and the source electrode are connected, the potential of the second semiconductor layer can be fixed to the potential of the source electrode. The potential of the second semiconductor layer can be fixed, and thus current collapse is suppressed, with the result that the dynamic characteristics of the nitride semiconductor device can be improved.

For example, the first semiconductor layer may include a plurality of layers each of which has a different impurity concentration, and the bottom of the first opening may be located in an nth layer from an uppermost layer among the plurality of layers where n is a natural number greater than or equal to two.

In this way, the first semiconductor layer includes a plurality of layers, and each layer can be caused to have a suitable function. For example, while an increase in the on resistance of the nitride semiconductor device is being suppressed, the off characteristics can be improved.

For example, the bottom of the groove may be located in a layer above the nth layer. For example, the plurality of layers may be two layers.

In this way, for example, the impurity concentration of the nth layer in which the bottom of the first opening is located can be higher than that of the layer in which the bottom of the groove is located. In the pn junction of the second semiconductor layer and the layer having a low impurity concentration in the first semiconductor layer, electric field relaxation in an off state can be performed, with the result that the off characteristics can be improved.

In the nth layer having a high impurity concentration and a low resistance, the bottom of the first opening is located, and thus on the path of a drain current, a layer having a low impurity concentration and a high resistance is not located. Hence, it is possible to suppress an increase in the on resistance. Although in the first opening, a layer having a low impurity concentration and a high resistance is not located, the pn junction of the semiconductor multilayer and the fourth semiconductor layer has a high quality and a high electric field strength, and thus electric field concentration in an off state can be received. Hence, it is possible to suppress the deterioration of the off characteristics of the nitride semiconductor device.

For example, the plurality of layers may be three layers.

In this way, it is possible to increase the number of functions included in the first semiconductor layer, and thus it is possible to improve the electrical properties of the nitride semiconductor device.

For example, the nth layer may have a highest impurity concentration among the plurality of layers.

In this way, the diffusion of the drain current in a lateral direction can be promoted via the layer having the highest impurity concentration, and thus it is possible to maximize the effect of reducing the on resistance.

For example, the uppermost layer among the plurality of layers may have a lower impurity concentration of the first conductivity type than the nth layer. For example, the bottom of the groove may be located in the nth layer.

In this way, when a reverse conduction operation is performed, it is possible to make it difficult for current to flow through the pn junction of the second semiconductor layer and a lower layer portion in the first semiconductor layer. If current flows through the pn junction described above by the reverse conduction operation, the deterioration of the off characteristics of the nitride semiconductor device (referred to as the deterioration of reverse conduction) occurs. In the nitride semiconductor device according to the present aspect, the deterioration of reverse conduction can be suppressed.

For example, the bottom of the groove may be located in the uppermost layer.

In this way, in the vicinity of the groove, a depletion layer easily extends laterally (that is, in a direction parallel to the main surface of the substrate) of the uppermost layer in the first semiconductor layer, and thus it is possible to perform electric field relaxation. Hence, the off characteristics of the nitride semiconductor device can be improved.

For example, the uppermost layer may include C or Fe.

In this way, it is possible to increase the resistance of the uppermost layer in the first semiconductor layer.

For example, the nitride semiconductor device according to the aspect of the present embodiment may further include: an insulating film which is provided along an inner surface of the groove; and a field plate which is provided above the insulating film to overhang the groove.

In this way, the electric field concentrated on the end portion can be distributed to the field plate. Hence, it is possible to more relax the electric field concentration on the pn junction in the vicinity of the groove including etching damage. Therefore, the off characteristics of the nitride semiconductor device can be improved.

For example, the field plate may be electrically connected to the source electrode.

In this way, it is possible to make the best use of the effect of distributing the electric field concentrated on the end portion to the field plate, and thus it is possible to more enhance the effect of relaxing the electric field concentration on the pn junction in the vicinity of the groove.

For example, a smaller angle of angles formed by a side wall of the groove and a plane parallel to a main surface of the substrate may be less than 90°.

In this way, it is possible to increase the coverage of the insulating film on the inner surface of the groove, and thus it is possible to more enhance the effect of relaxing the electric field concentration on the pn junction in the vicinity of the groove.

For example, the groove may be provided in a ring shape in plan view to collectively surround the first opening, the semiconductor multilayer, the fourth semiconductor layer, the gate electrode, and the source electrode, and the first semiconductor layer may include a high resistance region which is provided in a ring shape along the bottom of the groove and into which an impurity is introduced.

In the bottom of the groove, an interface level is formed at an interface between the insulating film and the first semiconductor layer, and thus a leakage current path may be formed. A leakage current flows via the path, and thus the off characteristics are lowered. By contrast, in the nitride semiconductor device according to the present aspect, the flow of the leakage current can be suppressed by the high resistance region, and thus it is possible to improve the off characteristics.

For example, the impurity included in the high resistance region may be Mg, B, or Fe.

In this way, it is possible to increase the resistance of the high resistance region.

For example, the high resistance region may include an end surface of the nitride semiconductor device.

The end surface of the nitride semiconductor device is formed, for example, by dicing or the like. A leakage current path may be formed due to damage caused by dicing. By contrast, in the nitride semiconductor device according to the present aspect, the flow of the leakage current can be suppressed by the high resistance region, and thus it is possible to improve the off characteristics.

Embodiments will be specifically described below with reference to drawings.

Each of the embodiments described below shows a comprehensive or specific example. Numerical values, shapes, materials, constituent elements, the arrangement and connection of the constituent elements, steps, the order of the steps, and the like shown in the following embodiments are examples, and are not intended to limit the present disclosure. Among the constituent elements in the following embodiments, constituent elements which are not recited in the independent claim are described as optional constituent elements.

The drawings are schematic views and are not exactly shown. Hence, for example, scales and the like are not necessarily the same in the drawings. In the drawings, substantially the same configurations are identified with the same reference signs, and repeated descriptions are omitted or simplified.

In the present specification, terms such as parallel and orthogonal which indicate relationships between elements, terms such as rectangular and trapezoid which indicate the shapes of elements, and numerical ranges are expressions which not only indicate exact meanings but also indicate substantially equivalent ranges such as a range including a several percent difference.

In the present specification and the drawings, an x-axis, a y-axis, and a z-axis indicate three axes of a three-dimensional orthogonal coordinate system. When the shape of a substrate in plan view is a rectangle, the x-axis and the y-axis respectively extend in a direction parallel to a first side of the rectangle and in a direction parallel to a second side orthogonal to the first side. The z-axis extends in the direction of thickness of the substrate. In the present specification, the “direction of thickness” of the substrate refers to a direction perpendicular to the main surface of the substrate. The direction of thickness is the same as the stacking direction of semiconductor layers, and is also referred to as a “longitudinal direction”. A direction parallel to the main surface of the substrate may be referred to as a “lateral direction”.

The side (the positive side of the z-axis) on which a gate electrode and a source electrode are provided with respect to the substrate is regarded as being “upward” or an “upward side”, and the side (the negative side of the z-axis) on which a drain electrode is provided with respect to the substrate is regarded as being “downward” or a “downward side”.

In the present specification, terms of “upward” and “downward” do not indicate an upward direction (vertically upward) and a downward direction (vertically downward) in absolute spatial recognition but are used as terms for defining a relative positional relationship based on a stacking order in a stacking configuration. The terms of “upward” and “downward” are applied not only to a case where two constituent elements are spaced with another constituent element present between the two constituent elements but also to a case where two constituent elements are arranged in close contact with each other to be in contact with each other.

In the present specification, “in plan view” means that the main surface of the substrate of a nitride semiconductor device is viewed in a direction perpendicular to the main surface, that is, that the main surface of the substrate is viewed from the front.

In the present specification, unless otherwise specified, ordinal numbers such as “first” and “second” do not mean the number or order of constituent elements but are used to avoid confusion of similar constituent elements and to distinguish between them.

In the present specification, AlGaN indicates a ternary mixed crystal of AlₓGa₁₋ₓN (0<x<1). In the following description, multinary mixed crystals are abbreviated by the sequences of constituent element symbols such as AlInN and GaInN. For example, AlₓGa_{1-x-y}In_{y}N (0<x<1, 0<y<1, and 0<x+y<1) which is an example of a nitride semiconductor is abbreviated as AlGaInN.

### Embodiment 1

### [Outline]

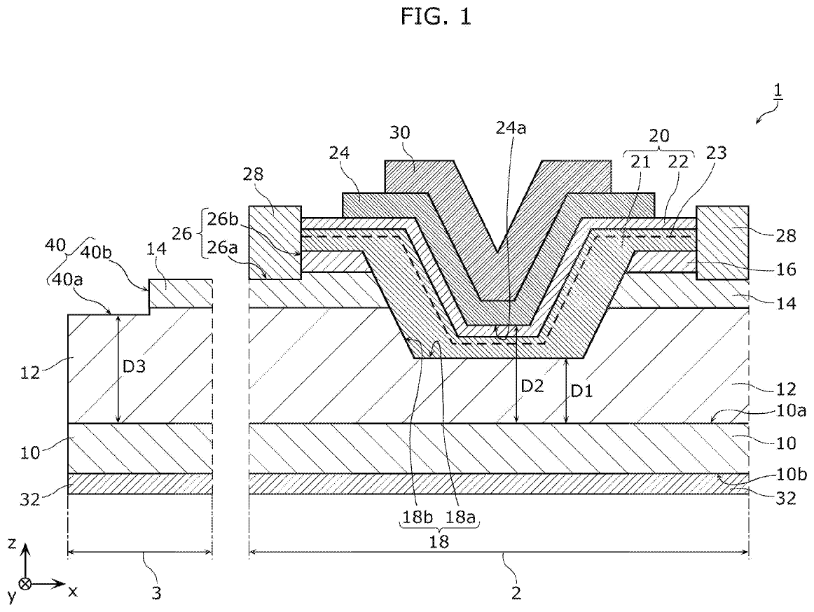

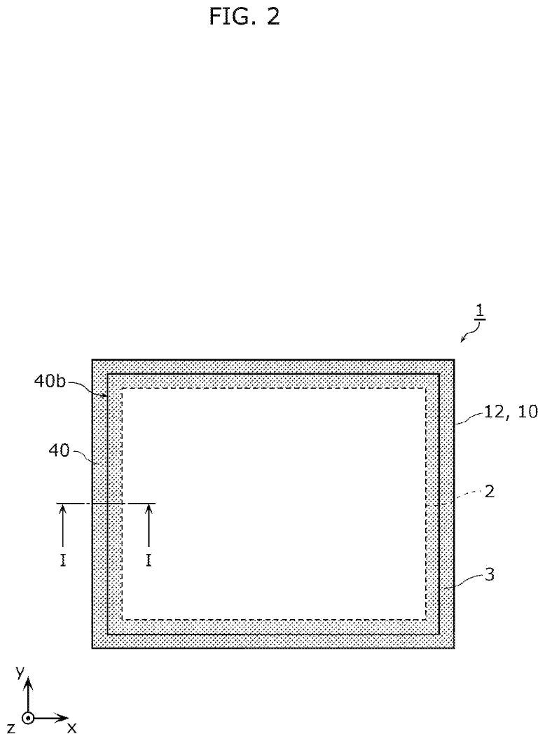

An outline of a nitride semiconductor device according to Embodiment 1 will first be described with reference to FIGS. 1 and 2.

FIG. 1 is a cross-sectional view of nitride semiconductor device 1 according to the present embodiment. FIG. 2 is a plan view of nitride semiconductor device 1 according to the present embodiment. FIG. 1 shows a cross section taken along line I-I in FIG. 2. In FIG. 1, a portion between transistor portion 2 and end portion 3 is schematically shown such that transistor portion 2 and end portion 3 are separated.

As shown in FIG. 1, nitride semiconductor device 1 includes transistor portion 2 and end portion 3. Specifically, nitride semiconductor device 1 includes substrate 10, drift layer 12, first base layer 14, second base layer 16, gate opening 18, semiconductor multilayer 20, threshold adjustment layer 24, source opening 26, source electrode 28, gate electrode 30, and drain electrode 32. Semiconductor multilayer 20 is a multilayer of electron transport layer 21 and electron supply layer 22, and includes 2-dimensional electron gas (2DEG) 23 serving as a channel region. Nitride semiconductor device 1 also includes groove 40 which is provided in end portion 3.

Transistor portion 2 is a region which includes an FET, and also includes the center of nitride semiconductor device 1 as shown in FIG. 2. Specifically, transistor portion 2 is a region in which second base layer 16, gate opening 18, semiconductor multilayer 20, threshold adjustment layer 24, gate electrode 30, and source electrode 28 are arranged in plan view.

In FIG. 2, constituent elements arranged in transistor portion 2 are omitted. In an example, a plurality of source electrodes 28 elongated in one direction in plan view are arranged in stripes, and gate electrode 30, threshold adjustment layer 24, and gate opening 18 are arranged between adjacent source electrodes 28. A plurality of source electrodes 28 which are hexagonal in plan view may also be spaced to fill a plane.

End portion 3 is a region other than transistor portion 2, and is provided in a ring shape to surround transistor portion 2. In end portion 3, second base layer 16, gate opening 18, semiconductor multilayer 20, threshold adjustment layer 24, gate electrode 30, and source electrode 28 are not arranged.

In the present embodiment, nitride semiconductor device 1 has a stacking structure of semiconductor layers which include, as main components, nitride semiconductors such as GaN and AlGaN. Specifically, nitride semiconductor device 1 has a heterostructure of an AlGaN film and a GaN film.

In the heterostructure of the AlGaN film and the GaN film, high-concentration 2-dimensional electron gas 23 is generated at a heterointerface by spontaneous polarization or piezoelectric polarization on a (0001) plane. Hence, even in an undoped state, a sheet carrier concentration of 1×10¹³ cm⁻² or more can be obtained at the interface.

Nitride semiconductor device 1 according to the present embodiment is a field effect transistor (FET) which utilizes, as a channel, 2-dimensional electron gas 23 generated at the heterointerface of AlGaN/GaN. Specifically, nitride semiconductor device 1 is a so-called vertical FET.

Nitride semiconductor device 1 according to the present embodiment is a normally-off FET. In nitride semiconductor device 1, for example, source electrode 28 is grounded (that is, its potential is 0 V), and a positive potential is applied to drain electrode 32. Although the potential applied to drain electrode 32 is, for example, greater than or equal to 100 V and less than or equal to 1200 V, the potential is not limited to this range. When nitride semiconductor device 1 is off, 0 V or a negative potential (for example, −5 V) is applied to gate electrode 30. When nitride semiconductor device 1 is on, a positive potential (for example, +5 V) is applied to gate electrode 30. Nitride semiconductor device 1 may be a normally-on FET.

### [Configuration]

Constituent elements included in nitride semiconductor device 1 will be described in detail below.

Substrate 10 is a substrate of nitride semiconductors, and includes, as shown in FIG. 1, first main surface 10a and second main surface 10b which face away from each other. First main surface 10a is a main surface (upper surface) on the side on which drift layer 12 is formed. Specifically, first main surface 10a substantially coincides with a c-plane. Second main surface 10b is a main surface (lower surface) on the side on which drain electrode 32 is formed. Although the shape of substrate 10 in plan view is, for example, a rectangle, the shape is not limited to the rectangle.

Substrate 10 is, for example, a substrate of n⁺ type GaN in which its thickness is 300 μm and its carrier concentration is 1×10¹⁸ cm⁻³. The n type and the p type each indicate the conductivity type of a semiconductor. The n⁺ type indicates a state where a high-concentration n type dopant is added into a semiconductor, that is, a so-called heavily doped state. The n⁻ type indicates a state where a low-concentration n type dopant is added into a semiconductor, that is, a so-called lightly doped state. The same is true for the p⁺ type and the p⁻ type. The n type, the n⁺ type, and the n⁻ type are examples of a first conductivity type. The p type, the p⁺ type, and the p⁻ type are examples of a second conductivity type. The second conductivity type is the opposite polarity conductivity type of the first conductivity type.

Substrate 10 does not need to be a substrate of a nitride semiconductor. For example, substrate 10 may be a silicon (Si) substrate, a silicon carbide (SiC) substrate, a zinc oxide (ZnO) substrate, or the like.

Drift layer 12 is an example of a first nitride semiconductor layer of the first conductivity type which is disposed above substrate 10. Drift layer 12 is, for example, a film of n⁻ type GaN which has a thickness of 8 μm. The donor concentration of drift layer 12 is, for example, in a range greater than or equal to 1×10¹⁵ cm⁻³ and less than or equal to 1×10¹⁷ cm⁻³, and an example of the donor concentration is 1×10¹⁶ cm⁻³. The carbon concentration (C concentration) of drift layer 12 is in a range greater than or equal to 1×10¹⁵ cm⁻³ and less than or equal to 2×10¹⁷ cm⁻³.

For example, drift layer 12 is provided in contact with first main surface 10a of substrate 10. Drift layer 12 is formed on first main surface 10a of substrate 10, for example, by crystal growth such as metalorganic vapor phase epitaxial growth (MOVPE).

First base layer 14 is an example of a second nitride semiconductor layer of the second conductivity type which is disposed above drift layer 12. First base layer 14 is, for example, a film of p type GaN in which its thickness is 400 nm and its carrier concentration is 1×10¹⁷ cm⁻³. First base layer 14 is provided in contact with the upper surface of drift layer 12. First base layer 14 is formed on drift layer 12, for example, by crystal growth such as MOVPE. First base layer 14 may be formed by implanting magnesium (Mg) into an undoped GaN film which has been formed. The “undoped” will be described later.

First base layer 14 suppresses a leakage current between source electrode 28 and drain electrode 32. For example, when a reverse voltage is applied to a pn junction formed by first base layer 14 and drift layer 12, and specifically, when the potential of drain electrode 32 is higher than that of source electrode 28, a depletion layer extends to drift layer 12. In this way, it is possible to achieve high voltage resistance of nitride semiconductor device 1. As described above, in the present embodiment, both in an off state and in an on state, the potential of drain electrode 32 is higher than that of source electrode 28. Hence, high voltage resistance of nitride semiconductor device 1 is realized.

In the present embodiment, as shown in FIG. 1, first base layer 14 is in contact with source electrode 28. Hence, the potential of first base layer 14 is fixed to the same potential as that of source electrode 28.

Second base layer 16 is an example of a third nitride semiconductor layer which is provided above first base layer 14. Second base layer 16 is a high resistance layer whose resistance is higher than that of first base layer 14. Second base layer 16 is formed of an insulating or semi-insulating nitride semiconductor. For example, second base layer 16 is a film of undoped GaN which has a thickness of 200 nm. Second base layer 16 is provided in contact with first base layer 14. Second base layer 16 is formed on first base layer 14, for example, by crystal growth such as MOVPE.

Here, the “undoped” means that GaN is not doped with a dopant such as Si or Mg which changes the polarity of GaN to the n type or the p type. In the present embodiment, second base layer 16 is doped with carbon (C). Specifically, the carbon concentration of second base layer 16 is higher than that of first base layer 14.

Second base layer 16 may include silicon (Si) or oxygen (O) which is mixed during film formation. In this case, the carbon concentration of second base layer 16 is higher than the silicon concentration (Si concentration) or the oxygen concentration (O concentration). Although for example, the carbon concentration of second base layer 16 is greater than or equal to 3×10¹⁷ cm⁻³, the carbon concentration may be greater than or equal to 1×10¹⁸ cm⁻³. Although the silicon concentration or the oxygen concentration of second base layer 16 is, for example, less than or equal to 5×10¹⁶ cm⁻³, the silicon concentration or the oxygen concentration may be less than or equal to 2×10¹⁶ cm⁻³.

Second base layer 16 may be formed by ion implantation of magnesium (Mg), iron (Fe), boron (B), or the like other than carbon. Other ion species may be used as long as they can realize the high resistance of GaN.

Here, if nitride semiconductor device 1 does not include second base layer 16, a parasitic npn structure of electron transport layer 21, p type first base layer 14, and n type drift layer 12, that is, a parasitic bipolar transistor is present between source electrode 28 and drain electrode 32. Hence, when nitride semiconductor device 1 is off, if current flows through p type first base layer 14, the parasitic bipolar transistor is turned on, with the result that the voltage resistance of nitride semiconductor device 1 may be lowered. In this case, nitride semiconductor device 1 is more likely to malfunction. In the present embodiment, high resistance second base layer 16 is provided, and thus the formation of the parasitic npn structure is suppressed, with the result that it is possible to suppress the malfunction of nitride semiconductor device 1.

On the upper surface of second base layer 16, a layer for suppressing the diffusion of p type impurities such as Mg from first base layer 14 may be provided. For example, on second base layer 16, an AlGaN layer having a thickness of 20 nm may be provided.

Gate opening 18 is an example of a first opening which penetrates through second base layer 16 and first base layer 14 to reach drift layer 12. Gate opening 18 penetrates through both second base layer 16 and first base layer 14. Bottom 18a of gate opening 18 is a portion of the upper surface of drift layer 12. As shown in FIG. 1, bottom 18a is located lower than the lower surface of first base layer 14. The lower surface of first base layer 14 corresponds to an interface between first base layer 14 and drift layer 12. For example, bottom 18a is parallel to first main surface 10a of substrate 10.

In the present embodiment, gate opening 18 is formed such that the opening area of gate opening 18 increases as the distance from substrate 10 increases. Specifically, side wall 18b of gate opening 18 is inclined. As shown in FIG. 1, the cross-sectional shape of gate opening 18 is an inverted trapezoid, and more specifically, is an inverted isosceles trapezoid.

For example, the inclination angle of side wall 18b relative to bottom 18a is in a range greater than or equal to 30° and less than or equal to 45°. As the inclination angle is decreased, side wall 18b is brought closer to a c-plane, with the result that it is possible to enhance the film quality of electron transport layer 21 and the like formed along side wall 18b by crystal regrowth. On the other hand, as the inclination angle is increased, an excessive increase in the size of gate opening 18 is suppressed, with the result that the size of nitride semiconductor device 1 is reduced.

Gate opening 18 is formed by continuously forming, on first main surface 10a of substrate 10, drift layer 12, first base layer 14, and second base layer 16 in this order and thereafter removing portions of second base layer 16 and first base layer 14 such that drift layer 12 is partially exposed. Here, a surface layer portion of drift layer 12 corresponding to a predetermined thickness is removed, and thus bottom 18a of gate opening 18 is formed lower than the lower surface of first base layer 14.

The removal of second base layer 16 and first base layer 14 is performed by application and patterning of a resist and dry etching. Specifically, the resist is patterned and is then baked, and thus an end of the resist is inclined. Thereafter, dry etching is performed, and thus the shape of the resist is transferred, with the result that gate opening 18 having inclined side wall 18b is formed.

A portion of semiconductor multilayer 20 is disposed along the inner surface of gate opening 18, and another portion is disposed above second base layer 16. Semiconductor multilayer 20 is a multilayer of electron transport layer 21 and electron supply layer 22.

Electron transport layer 21 is an example of a first regrown layer which is provided along the inner surface of gate opening 18. Specifically, a portion of electron transport layer 21 is provided along bottom 18a and side wall 18b of gate opening 18, and another portion is provided on the upper surface of second base layer 16. Electron transport layer 21 is, for example, a film of undoped GaN which has a thickness of 150 nm. Electron transport layer 21 may be not undoped but doped with Si or the like so as to be n type electron transport layer 21.

Electron transport layer 21 is in contact with drift layer 12 on bottom 18a and side wall 18b of gate opening 18. Electron transport layer 21 is in contact with end surfaces of first base layer 14 and second base layer 16 on side wall 18b of gate opening 18. Furthermore, electron transport layer 21 is in contact with the upper surface of second base layer 16. Electron transport layer 21 is formed by crystal regrowth after the formation of gate opening 18.

Electron transport layer 21 includes a channel region. Specifically, in the vicinity of an interface between electron transport layer 21 and electron supply layer 22, 2-dimensional electron gas 23 is generated. 2-dimensional electron gas 23 functions as the channel of electron transport layer 21. In FIG. 1, 2-dimensional electron gas 23 is schematically shown by a broken line. 2-dimensional electron gas 23 is curved along the interface between electron transport layer 21 and electron supply layer 22, that is, along the inner surface of gate opening 18.

Although not shown in FIG. 1, an AIN film having a thickness of about 1 nm may be provided as a second regrown layer between electron transport layer 21 and electron supply layer 22. The AlN film can suppress alloy scattering and enhance the mobility of the channel.

Electron supply layer 22 is an example of a third regrown layer which is provided along the inner surface of gate opening 18. Electron transport layer 21 and electron supply layer 22 are provided in this order from the side of substrate 10. Electron supply layer 22 is formed in a shape which is along the upper surface of electron transport layer 21 so as to have a substantially uniform thickness. Electron supply layer 22 is, for example, a film of undoped AlGaN which has a thickness of 50 nm. Electron supply layer 22 is formed by crystal regrowth following a step of forming electron transport layer 21.

Electron supply layer 22 forms the heterointerface of AlGaN/GaN with electron transport layer 21. In this way, 2-dimensional electron gas 23 is generated in electron transport layer 21. Electron supply layer 22 supplies electrons to the channel region (that is, 2-dimensional electron gas 23) formed in electron transport layer 21.

Threshold adjustment layer 24 is an example of a fourth nitride semiconductor layer of the second conductivity type which is disposed along the upper surface of semiconductor multilayer 20. Specifically, threshold adjustment layer 24 is provided between gate electrode 30 and electron supply layer 22. Threshold adjustment layer 24 is formed in a shape which is along the upper surface of electron supply layer 22 so as to have a substantially uniform thickness.

Threshold adjustment layer 24 is, for example, a nitride semiconductor layer of p type GaN or AlGaN in which its thickness is 100 nm and its carrier concentration is 1×10¹⁷ cm⁻³. Threshold adjustment layer 24 is formed by regrowth in MOVPE and patterning following a step of forming electron supply layer 22.

Threshold adjustment layer 24 is provided to raise the potential of the conduction band edge of a channel portion. Hence, it is possible to increase the threshold voltage of nitride semiconductor device 1. Therefore, it is possible to realize nitride semiconductor device 1 as a normally-off FET. In other words, when a potential of V is applied to gate electrode 30, nitride semiconductor device 1 can be turned off.

Source opening 26 is an example of a second opening which penetrates through semiconductor multilayer 20 and second base layer 16 to reach first base layer 14 in a position distant from gate opening 18. Source opening 26 is disposed in the position distant from gate electrode 30 in plan view.

Bottom 26a of source opening 26 is a portion of the upper surface of first base layer 14. As shown in FIG. 1, bottom 26a is located lower than the lower surface of second base layer 16. The lower surface of second base layer 16 corresponds to an interface between second base layer 16 and first base layer 14. For example, bottom 26a is parallel to first main surface 10a of substrate 10.

As shown in FIG. 1, source opening 26 is formed such that the opening area of source opening 26 is constant regardless of the distance from substrate 10. Specifically, side wall 26b of source opening 26 is perpendicular to bottom 26a. In other words, the cross-sectional shape of source opening 26 is rectangular.

Source opening 26 may also be formed as with gate opening 18 such that the opening area increases as the distance from substrate 10 increases. Specifically, side wall 26b of source opening 26 may be inclined. For example, the cross-sectional shape of source opening 26 may be an inverted trapezoid, and more specifically, may be an inverted isosceles trapezoid. Here, the inclination angle of side wall 26b relative to bottom 26a may be, for example, in a range greater than or equal to 30° and less than or equal to 60°. For example, the inclination angle of side wall 26b of source opening 26 may be greater than the inclination angle of side wall 18b of gate opening 18. Side wall 26b is inclined, and thus a contact area between source electrode 28 and electron transport layer 21 (2-dimensional electron gas 23) is increased, with the result that an ohmic connection is easily made. 2-dimensional electron gas 23 is exposed to side wall 26b of source opening 26, and is connected to source electrode 28 at the exposed portion.

For example, source opening 26 is formed following a step of forming threshold adjustment layer 24 (that is, a step of crystal regrowth) by etching threshold adjustment layer 24, electron supply layer 22, electron transport layer 21, and second base layer 16 such that first base layer 14 is exposed in a region different from gate opening 18. Here, a surface layer portion of first base layer 14 is also removed, and thus bottom 26a of source opening 26 is formed lower than the lower surface of second base layer 16. Source opening 26 is formed in a predetermined shape by patterning using photolithography, dry etching and the like.

Source electrode 28 is disposed away from gate electrode 30. In the present embodiment, source electrode 28 is provided along the inner surface of source opening 26. Specifically, source electrode 28 is connected to electron supply layer 22, electron transport layer 21, and first base layer 14. Source electrode 28 is ohmically connected to electron transport layer 21 and electron supply layer 22. Source electrode 28 is in direct contact with 2-dimensional electron gas 23 on side wall 26b. In this way, it is possible to reduce the contact resistance of source electrode 28 and 2-dimensional electron gas 23 (channel).

Source electrode 28 is formed using a conductive material such as metal. As the material of source electrode 28, for example, a material such as Ti/AI which is thermally processed to be ohmically connected to an n type GaN layer can be used. Source electrode 28 is formed, for example, by patterning a conductive film formed by sputtering or vapor deposition.

Gate electrode 30 is disposed above threshold adjustment layer 24. Specifically, gate electrode 30 is provided in contact with the upper surface of threshold adjustment layer 24 so as to cover gate opening 18. For example, gate electrode 30 is formed in a shape which is along the upper surface of threshold adjustment layer 24 so as to have a substantially uniform thickness. Gate electrode 30 may also be formed to fill a depression in the upper surface of threshold adjustment layer 24.

Gate electrode 30 is formed using a conductive material such as metal. For example, gate electrode 30 is formed using palladium (Pd). As the material of gate electrode 30, a material which is Schottky-connected to a p type GaN layer can be used, and examples of the material which can be used include a nickel (Ni)-based material, tungsten silicide (WSi), gold (Au), and the like. Gate electrode 30 is formed, after the formation of threshold adjustment layer 24, after the formation of source opening 26, or after the formation of source electrode 28, for example, by patterning a conductive film formed by sputtering, vapor deposition or the like.

Drain electrode 32 is provided on the side of the lower surface of substrate 10, that is, on the side opposite to drift layer 12. Specifically, drain electrode 32 is provided in contact with second main surface 10b of substrate 10. Drain electrode 32 is formed using a conductive material such as metal. As the material of drain electrode 32, as with the material of source electrode 28, for example, a material such as Ti/AI which is ohmically connected to an n type GaN layer can be used. Drain electrode 32 is formed, for example, by patterning a conductive film formed by sputtering, vapor deposition or the like.

### [Characteristic Configuration]

The characteristic configuration of nitride semiconductor device 1 according to the present embodiment will then be described.

As shown in FIG. 1, in end portion 3, second base layer 16, semiconductor multilayer 20, and threshold adjustment layer 24 are not provided. For example, at the same time when source opening 26 is formed, second base layer 16, semiconductor multilayer 20, and threshold adjustment layer 24 in end portion 3 are removed. In end portion 3, the upper surface of first base layer 14 is located at the same height as bottom 26a of source opening 26. The “at the same height” means that the distance from first main surface 10a of substrate 10 is the same.

In end portion 3, groove 40 is provided. Groove 40 is an isolation trench for partitioning and separating transistor portion 2. Groove 40 penetrates through first base layer 14 to reach drift layer 12.

Groove 40 includes bottom 40a and side wall 40b. In the present embodiment, groove 40 is a step portion which has side wall 40b only on the side of transistor portion 2. In other words, bottom 40a of groove 40 is connected to an end surface of nitride semiconductor device 1. As shown in FIG. 2, groove 40 is formed in a ring shape which surrounds transistor portion 2.

Bottom 40a of groove 40 is a portion of the upper surface of drift layer 12. As shown in FIG. 1, bottom 40a is located lower than the lower surface of first base layer 14. For example, bottom 40a is parallel to first main surface 10a of substrate 10.

As shown in FIG. 1, groove 40 is formed such that the opening area of groove 40 is constant regardless of the distance from substrate 10. Specifically, side wall 40b of groove 40 is perpendicular to bottom 40a. In other words, the cross-sectional shape of groove 40 is rectangular.

Groove 40 is formed following a dry etching step for forming source opening 26 by changing an etching mask and performing dry etching. Groove 40 may also be formed by dry etching after the formation of source electrode 28 or after the formation of gate electrode 30.

As shown in FIG. 1, a distance between bottom 18a of gate opening 18 and first main surface 10a of substrate 10 is assumed to be D1. A distance between bottom 24a of threshold adjustment layer 24 and first main surface 10a of substrate 10 is assumed to be D2. A distance between bottom 40a of groove 40 and first main surface 10a of substrate 10 is assumed to be D3.

In nitride semiconductor device 1, distance D1 is shorter than distance D3. Distance D2 is shorter than distance D3. In other words, D1<D2<D3 is established. For example, a difference between distance D1 and distance D3 is greater than or equal to 0.05 μm and less than or equal to 1 μm. The difference is more preferably greater than or equal to 0.1 μm and less than or equal to 0.5 μm. In this way, it is possible to improve the off characteristics of nitride semiconductor device 1. Specifically, details will be as described below.

When transistor portion 2 is off, a high voltage is applied between drain electrode 32 and source electrode 28 such that the side of drain electrode 32 is higher in potential than the side of source electrode 28. Hence, in the off state, a high electric field is generated in the longitudinal direction of nitride semiconductor device 1.

Since both distances D1 and D2 are shorter than distance D3, the electric field is more likely to be concentrated at gate opening 18 of transistor portion 2 than at end portion 3. The concentrated electric field can be received by the pn junction of threshold adjustment layer 24 and semiconductor multilayer 20. This pn junction has a higher quality and a higher electric field strength than the pn junction of first base layer 14 and drift layer 12 in the vicinity of groove 40 subjected to etching damage. Since electric field concentration can be received by the pn junction of a high electric field strength, it is possible to relax electric field concentration on the pn junction in the vicinity of groove 40. In this way, it is possible to improve the off characteristics of nitride semiconductor device 1. Specifically, it is possible to reduce a leakage current in the vicinity of groove 40 and to suppress a decrease in voltage resistance. As the difference between distance D1 and distance D3 is increased, electric field concentration in the vicinity of groove 40 can be more relaxed.

### Embodiment 2

Embodiment 2 will then be described.

Embodiment 2 differs from Embodiment 1 in that the drift layer has a two-layer structure. Differences from Embodiment 1 will be mainly described below, and common description is omitted or simplified.

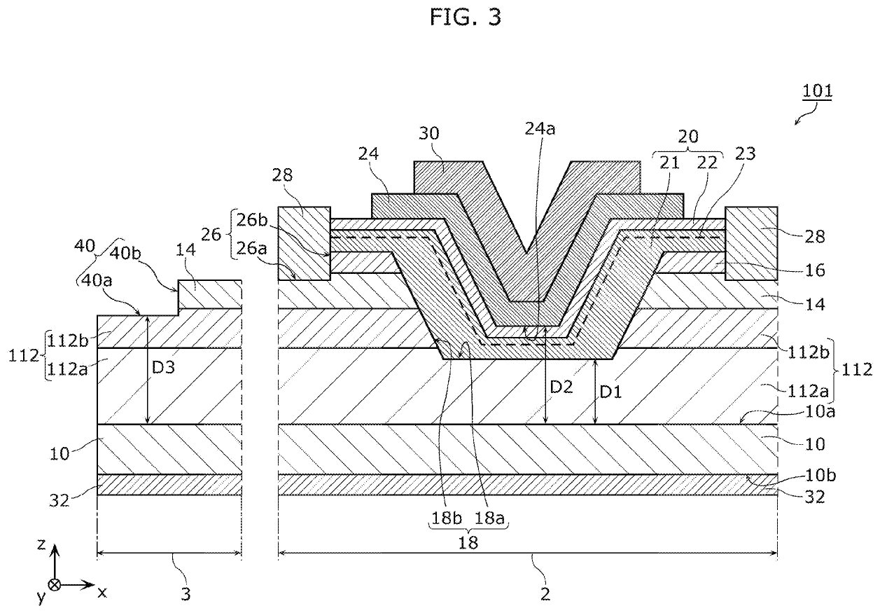

FIG. 3 is a cross-sectional view of nitride semiconductor device 101 according to the present embodiment. As shown in FIG. 3, nitride semiconductor device 101 differs from nitride semiconductor device 1 according to Embodiment 1 in that nitride semiconductor device 101 includes drift layer 112 instead of drift layer 12.

Drift layer 112 includes a plurality of layers each of which has a different impurity concentration. In the present embodiment, the plurality of layers are two layers. Specifically, as shown in FIG. 3, drift layer 112 includes high-concentration layer 112a and low-concentration layer 112b. High-concentration layer 112a and low-concentration layer 112b are continuously formed on substrate 10, for example, by crystal growth such as MOVPE.

High-concentration layer 112a is an example of an nth layer from the uppermost layer among the plurality of layers. Here, n is a natural number greater than or equal to two. In the present embodiment, n is two. High-concentration layer 112a is provided in contact with first main surface 10a of substrate 10. In high-concentration layer 112a, bottom 18a of gate opening 18 is located.

High-concentration layer 112a is, for example, a film of n⁺ type GaN which has a thickness of 7 μm. The impurity concentration (donor concentration) of high-concentration layer 112a is, for example, in a range greater than or equal to 3×10¹⁵ cm⁻³ and less than or equal to 5×10¹⁶ cm⁻³, and an example of high-concentration layer 112a is 1.5×10¹⁶ cm⁻³.

Low-concentration layer 112b is an example of a layer which is located above the nth layer. In the present embodiment, low-concentration layer 112b is the uppermost layer in drift layer 112, and is provided between high-concentration layer 112a and first base layer 14 in contact with high-concentration layer 112a and first base layer 14. Low-concentration layer 112b is lower in impurity concentration than high-concentration layer 112a. In low-concentration layer 112b, bottom 40a of groove 40 is located.

Low-concentration layer 112b is, for example, a film of n⁻ type GaN which has a thickness of 1 μm. The impurity concentration (donor concentration) of low-concentration layer 112b is, for example, in a range greater than or equal to 1×10¹⁵ cm⁻³ and less than or equal to 3×10¹⁶ cm⁻³, and an example of low-concentration layer 112b is 9×10¹⁵ cm⁻³.

As described above, the impurity concentration of low-concentration layer 112b on the side (upper side) of first base layer 14 is set lower than the donor concentration of high-concentration layer 112a on a side (lower side) closer to substrate 10, and thus when a high voltage is applied to drain electrode 32 in an off state, the extension of the depletion layer into drift layer 112 is promoted. In this way, it is possible to enhance the voltage resistance of nitride semiconductor device 101.

In the present embodiment, as in Embodiment 1, distance D3 is shorter than both distances D1 and D2, and thus as in Embodiment 1, the off characteristics of nitride semiconductor device 101 can be improved.

Bottom 18a of gate opening 18 is located in high-concentration layer 112a. In this way, a drain current in an on state flows from drain electrode 32 through substrate 10, high-concentration layer 112a, and 2-dimensional electron gas 23 to source electrode 28. On the path of the drain current, low-concentration layer 112b of a high resistance is not present, and thus it is possible to reduce an on resistance.

### Embodiment 3

Embodiment 3 will then be described.

Embodiment 3 differs from Embodiment 2 in the number of layers in the drift layer. Differences from Embodiment 2 will be mainly described below, and common description is omitted or simplified.

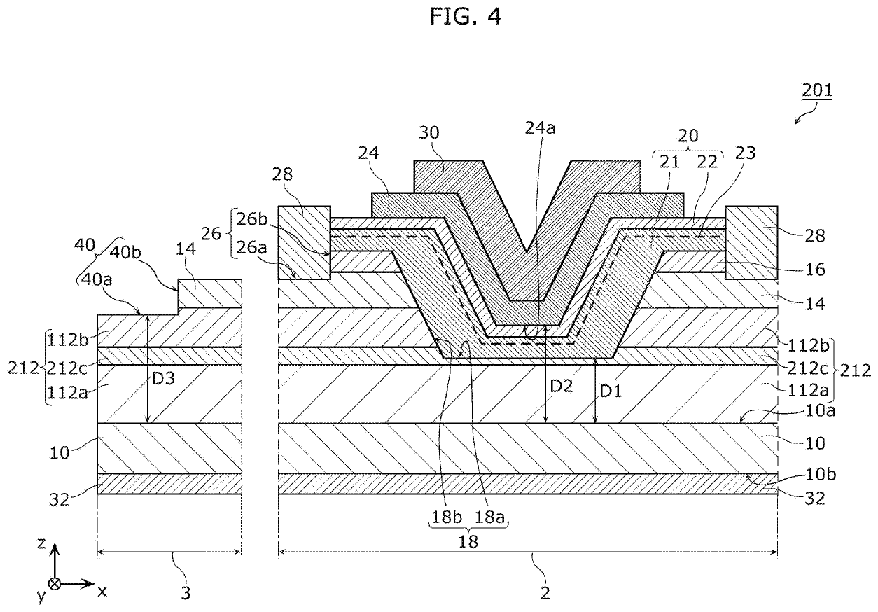

FIG. 4 is a cross-sectional view of nitride semiconductor device 201 according to the present embodiment. As shown in FIG. 4, nitride semiconductor device 201 differs from nitride semiconductor device 101 according to Embodiment 2 in that nitride semiconductor device 201 includes drift layer 212 instead of drift layer 112.

Drift layer 212 includes a plurality of layers each of which has a different impurity concentration. In the present embodiment, the plurality of layers are three layers. Specifically, as shown in FIG. 4, drift layer 212 includes high-concentration layer 112a, ultrahigh-concentration layer 212c, and low-concentration layer 112b. High-concentration layer 112a and low-concentration layer 112b are the same as in Embodiment 2. High-concentration layer 112a, ultrahigh-concentration layer 212c, and low-concentration layer 112b are continuously formed on substrate 10, for example, by crystal growth such as MOVPE.

Ultrahigh-concentration layer 212c is an example of an nth layer among the plurality of layers. In other words, in the present embodiment, high-concentration layer 112a is a layer which is located below the nth layer. Here, n is two. Ultrahigh-concentration layer 212c is provided between high-concentration layer 112a and low-concentration layer 112b in contact with high-concentration layer 112a and low-concentration layer 112b. Ultrahigh-concentration layer 212c has the highest impurity concentration among the layers of drift layer 212.

Ultrahigh-concentration layer 212c is, for example, a film of n⁺ type GaN which has a thickness of 0.2 μm. The impurity concentration (donor concentration) of ultrahigh-concentration layer 212c is, for example, in a range greater than or equal to 1×10¹⁶ cm⁻³ and less than or equal to 1×10¹⁸ cm⁻³, and an example of ultrahigh-concentration layer 212c is 1×10¹⁷ cm⁻³.

In ultrahigh-concentration layer 212c, bottom 18a of gate opening 18 is located. Since ultrahigh-concentration layer 212c has a high impurity concentration and a low resistance, the drain current passing through bottom 18a of gate opening 18 diffuses laterally in ultrahigh-concentration layer 212c. In other words, the diffusion of the drain current in the lateral direction in drift layer 212 is promoted, and thus it is possible to reduce the on resistance of nitride semiconductor device 201.

In the present embodiment, as in Embodiment 2, low-concentration layer 112b and first base layer 14 are connected, and thus the extension of the depletion layer into drift layer 212 is promoted. Hence, it is possible to enhance the voltage resistance of nitride semiconductor device 201. In nitride semiconductor device 201, as in Embodiment 1, the off characteristics can be improved.

### Embodiment 4

Embodiment 4 will then be described.

Embodiment 4 differs from Embodiment 2 in the impurity concentration of the uppermost layer in the drift layer. Differences from Embodiment 2 will be mainly described below, and common description is omitted or simplified.

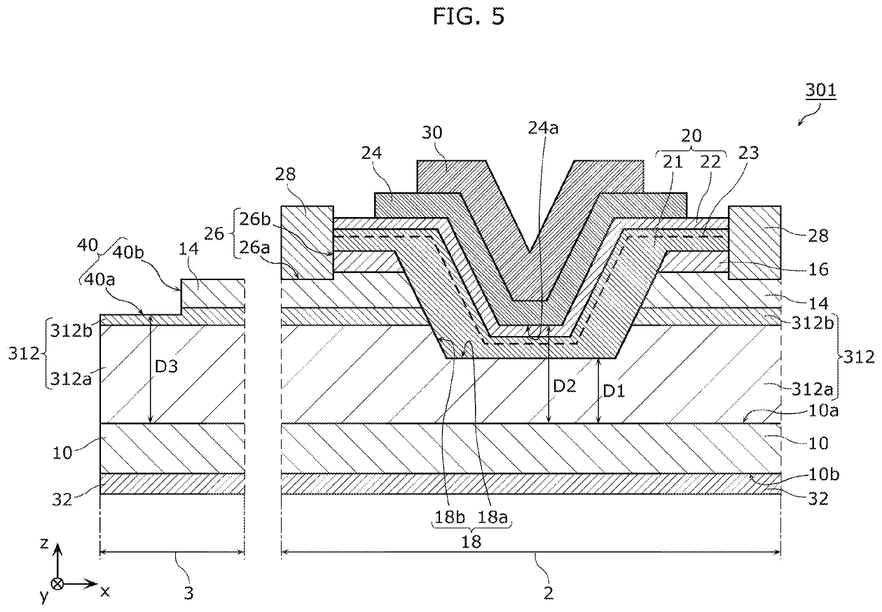

FIG. 5 is a cross-sectional view of nitride semiconductor device 301 according to the present embodiment. As shown in FIG. 5, nitride semiconductor device 301 differs from nitride semiconductor device 101 according to Embodiment 2 in that nitride semiconductor device 301 includes drift layer 312 instead of drift layer 112.

Drift layer 312 includes a plurality of layers each of which has a different impurity concentration. In the present embodiment, the plurality of layers are two layers. Specifically, as shown in FIG. 5, drift layer 312 includes low resistance layer 312a and high resistance layer 312b. Low resistance layer 312a is substantially the same as drift layer 12 in Embodiment 1. Low resistance layer 312a and high resistance layer 312b are continuously formed on substrate 10, for example, by crystal growth such as MOVPE.

High resistance layer 312b is the uppermost layer among the layers of drift layer 312. High resistance layer 312b is disposed between low resistance layer 312a and first base layer 14 in contact with low resistance layer 312a and first base layer 14. High resistance layer 312b has a lower impurity concentration of the first conductivity type than low resistance layer 312a. High resistance layer 312b has a higher resistance than both low resistance layer 312a and first base layer 14. For example, high resistance layer 312b is formed of an insulating or semi-insulating nitride semiconductor. The impurity concentration (donor concentration) of high resistance layer 312b is, for example, less than or equal to 1×16 cm⁻³. High resistance layer 312b is, for example, a film of undoped GaN which has a thickness of 200 nm.

High resistance layer 312b includes carbon (C) or iron (Fe). The carbon concentration or the iron concentration of high resistance layer 312b is, for example, in a range greater than or equal to 2×10¹⁶ cm⁻³ and less than or equal to 1×10²⁰ cm⁻³, and an example of the concentration is 1×10¹⁸ cm⁻³. Another element may be used as long as the element can realize the high resistance of GaN.

In the present embodiment, as shown in FIG. 5, bottom 40a of groove 40 is located in high resistance layer 312b. In other words, bottom 40a of groove 40 is a portion of the upper surface of high resistance layer 312b. In this way, in the vicinity of groove 40, the depletion layer easily extends laterally of high resistance layer 312b, and thus it is possible to perform electric field relaxation. Hence, the off characteristics of nitride semiconductor device 301 can be improved.

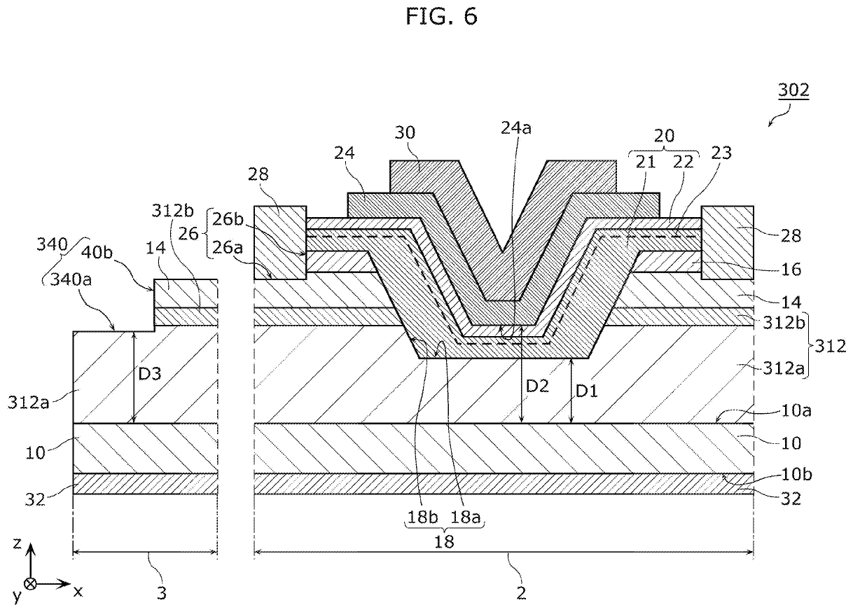

Groove 40 may penetrate through high resistance layer 312b. FIG. 6 is a cross-sectional view of nitride semiconductor device 302 according to a variation of the present embodiment. As shown in FIG. 6, nitride semiconductor device 302 includes groove 340 which penetrates through high resistance layer 312b. In other words, bottom 340a of groove 340 is a portion of the upper surface of low resistance layer 312a. Bottom 340a is located lower than an interface between high resistance layer 312b and low resistance layer 312a.

As described above, in the present embodiment and the variation, high resistance layer 312b is provided, and thus when a reverse conduction operation is performed in transistor portion 2, it is possible to make it difficult for current to flow through the pn junction of first base layer 14 and low resistance layer 312a. In this way, the deterioration of reverse conduction is suppressed, and thus it is possible to suppress the deterioration of the off characteristics of nitride semiconductor device 301 or 302.

### Embodiment 5

Embodiment 5 will then be described.

Embodiment 5 differs from Embodiment 2 in that a field plate is included. Differences from Embodiment 2 will be mainly described below, and common description is omitted or simplified.

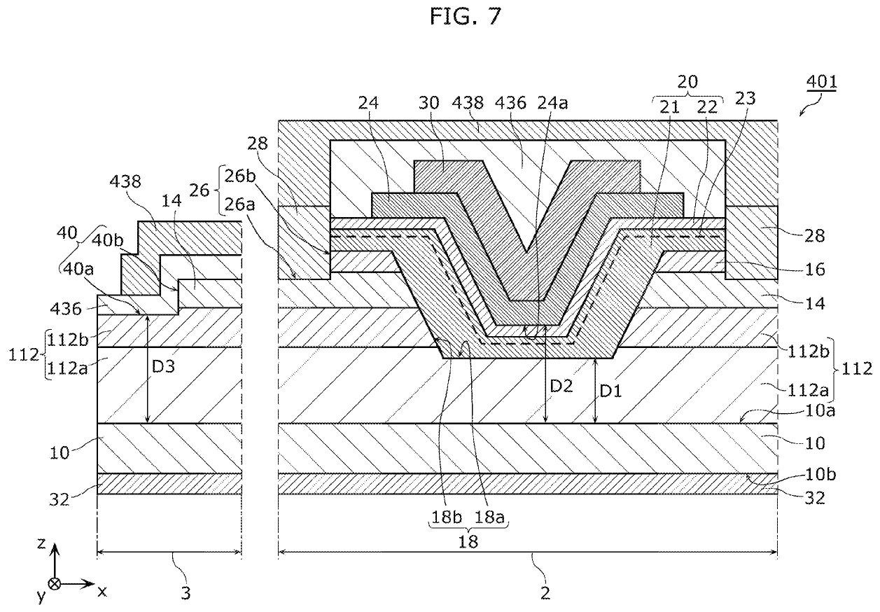

FIG. 7 is a cross-sectional view of nitride semiconductor device 401 according to the present embodiment. As shown in FIG. 7, nitride semiconductor device 401 includes insulating film 436 and field plate 438 in addition to the configuration of nitride semiconductor device 101 according to Embodiment 2.

Insulating film 436 is provided along the inner surface of groove 40. Specifically, insulating film 436 is provided to electrically insulate field plate 438 from constituent elements other than source electrode 28 (specifically, gate electrode 30, threshold adjustment layer 24, semiconductor multilayer 20, first base layer 14, and drift layer 112). For example, insulating film 436 is formed, after the formation of gate electrode 30 and groove 40, on the entire upper surface thereof, and is patterned to expose at least only a portion of source electrode 28. In other words, in insulating film 436, a contact hole for electrically connecting source electrode 28 and field plate 438 is formed. Insulating film 436 is, for example, a silicon oxide film, a silicon nitride film, an aluminum oxide film, or the like.

Field plate 438 is provided to overhang groove 40 above insulating film 436. In other words, field plate 438 overlaps bottom 40a of groove 40 in plan view.

Field plate 438 is formed using a conductive material such as metal. For example, as the material of field plate 438, the same material as that of source electrode 28 can be used. In the present embodiment, field plate 438 is electrically connected to source electrode 28. In other words, the same potential as that of source electrode 28 is supplied to field plate 438.

In end portion 3, an electric field in an off state is more likely to be concentrated at the intersection of bottom 40a and side wall 40b of groove 40, that is, the corner of groove 40. Field plate 438 is provided to overhang groove 40, and thus a portion of the electric field concentrated at the intersection of bottom 40a and side wall 40b can be distributed to the overhanging portion of field plate 438. In the vicinity of the intersection of bottom 40a and side wall 40b, a pn junction including etching damage is present, and thus electric field concentration on the pn junction is relaxed, with the result that it is possible to improve the off characteristics of nitride semiconductor device 401.

Although in the present embodiment, the example is shown where side wall 40b of groove 40 is perpendicular to bottom 40a, the present embodiment is not limited to this configuration. Side wall 40b may be inclined.

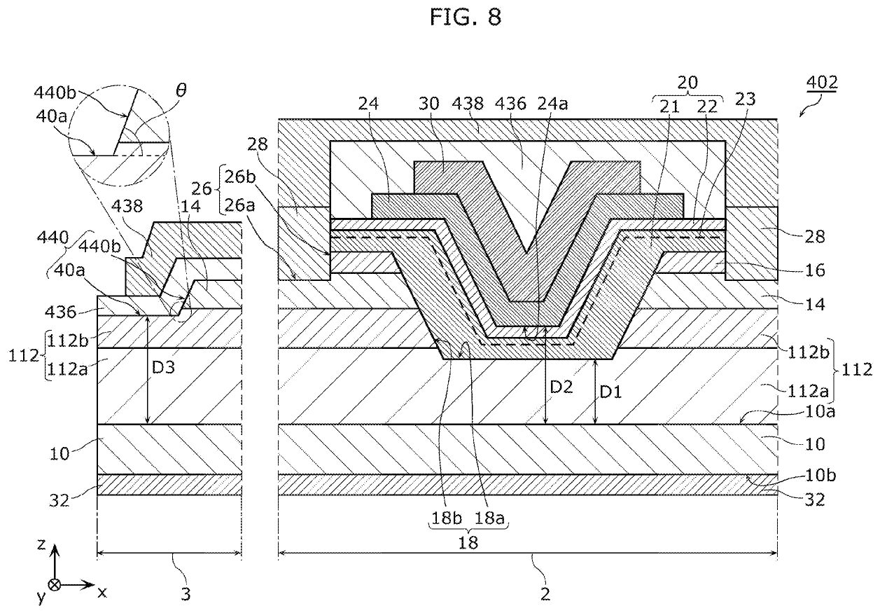

FIG. 8 is a cross-sectional view of nitride semiconductor device 402 according to Variation 1 of the present embodiment. As shown in FIG. 8, nitride semiconductor device 402 includes groove 440 instead of groove 40.

Groove 440 includes bottom 40a and side wall 440b. Bottom 40a is the same as in Embodiment 2, and is a portion of the upper surface of low-concentration layer 112b in drift layer 112. Bottom 40a is parallel to first main surface 10a of substrate 10.

Side wall 440b is inclined relative to bottom 40a. As enlarged and shown in FIG. 8, an inclination angle θ is less than 90°. For example, the inclination angle θ is greater than or equal to 30° and less than or equal to 85°. The inclination angle θ is the smaller angle of angles formed by side wall 440b and a plane parallel to first main surface 10a of substrate 10.

As the inclination angle θ is decreased, the coverage of insulating film 436 formed along the inner surface of groove 440 is enhanced, and thus it is possible to enhance the effect of relaxing electric field concentration on a pn junction in the vicinity of groove 440. As the inclination angle θ is increased, the width of groove 440 can be decreased, and thus a larger area of transistor portion 2 can be secured.

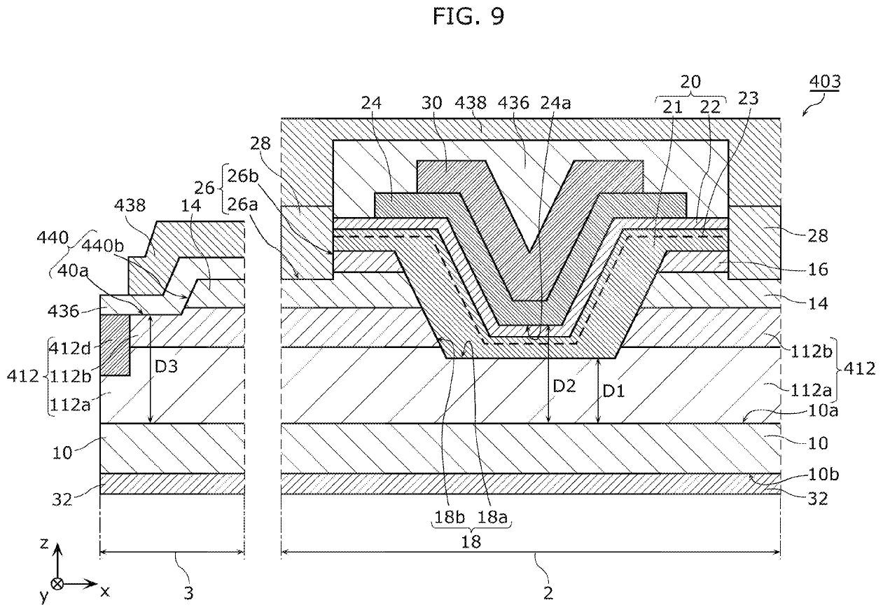

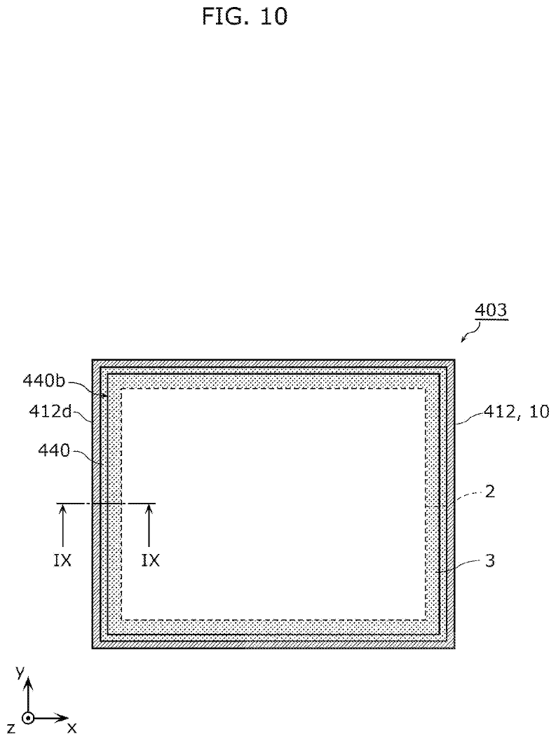

In a portion of drift layer 112 in which bottom 40a of groove 440 is formed, a high resistance region may be provided. FIG. 9 is a cross-sectional view of nitride semiconductor device 403 according to Variation 2 of the present embodiment. FIG. 10 is a plan view of nitride semiconductor device 403 according to Variation 2 of the present embodiment. FIG. 9 shows a cross section taken along line IX-IX in FIG. 10.

As shown in FIG. 9, nitride semiconductor device 403 differs from nitride semiconductor device 402 according to Variation 1 of the present embodiment in that nitride semiconductor device 403 includes drift layer 412 instead of drift layer 112. Drift layer 412 includes high-concentration layer 112a, low-concentration layer 112b, and high resistance region 412d. High-concentration layer 112a and low-concentration layer 112b are the same as in Embodiment 2.

High resistance region 412d is a region into which an impurity is introduced. The impurity is introduced into high resistance region 412d, and thus high resistance region 412d has a higher resistance than the adjacent regions. The impurity is, for example, magnesium (Mg), boron (B), or iron (Fe). For example, high resistance region 412d is formed by ion implantation after the formation of groove 40.

As shown in FIG. 10, high resistance region 412d is provided in a ring shape along bottom 40a of groove 440. Specifically, high resistance region 412d includes an end surface of nitride semiconductor device 403.

A plurality of nitride semiconductor devices 403 are simultaneously produced by separating a semiconductor wafer into pieces. Specifically, after the crystal growth of the nitride semiconductor layers on the semiconductor wafer (substrate 10), the formation of the openings, the crystal regrowth of the nitride semiconductor films, the formation of groove 440, the formation (ion implantation) of high resistance region 412d, and the formation of source electrode 28, gate electrode 30, and drain electrode 32, the semiconductor wafer is separated into pieces, with the result that a plurality of nitride semiconductor devices 403 are formed. The separation of the semiconductor wafer into pieces is performed, for example, by dicing. Here, dicing is performed along high resistance region 412d. In other words, the end surface cut by dicing is the end surface of nitride semiconductor device 403, and high resistance region 412d includes the end surface described above.

Since the end surface of nitride semiconductor device 403 is damaged by dicing, a leakage current path is easily formed. In the present variation, high resistance region 412d is formed to include the end surface described above, and thus the occurrence of a leakage current can be suppressed. High resistance region 412d as described above may be formed in groove 40 in the nitride semiconductor device according to each of Embodiments 1 to 4 and the variation.

As described above, in the present embodiment and the variations, field plate 438 is provided, and thus the off characteristics of nitride semiconductor devices 401, 402, and 403 can be improved.

Although in the present embodiment and the variations, the example is shown where field plate 438 is electrically connected to source electrode 28, the present embodiment is not limited to this configuration. Field plate 438 may be insulated from source electrode 28, and the same potential as or a different potential from source electrode 28 may be supplied as necessary. In this case, in insulating film 436, the contact hole for electrically connecting source electrode 28 and field plate 438 is not provided.

Although in the present embodiment and the variations, the example is shown which is based on the configuration of nitride semiconductor device 101 according to Embodiment 2, the present embodiment and the variations are not limited to this configuration. The nitride semiconductor device according to Embodiment 1, 3, or 4 or the variation thereof may include insulating film 436 and field plate 438 and may include groove 440.

### OTHER EMBODIMENTS

Although the nitride semiconductor device according to one or a plurality of aspects has been described above based on the embodiments, the present disclosure is not limited to these embodiments. Embodiments obtained by performing, on the present embodiments, various variations conceived by a person skilled in the art and embodiments established by combining constituent elements in different embodiments are also included in the scope of the present disclosure as long as they do not depart from the spirit of the present disclosure.

For example, source opening 26 does not need to be provided. In this case, source electrode 28 is provided in a position distant from threshold adjustment layer 24 on the upper surface of semiconductor multilayer 20.

For example, drift layer 12 may have a graded structure in which the impurity concentration (donor concentration) is gradually reduced from the side of substrate 10 to the side of first base layer 14. The donor concentration may be controlled by Si which serves as a donor or may be controlled by carbon which serves as an acceptor for compensating for Si.

Although the example is shown where the number of layers stacked in the drift layer is two or three, the number of layers stacked is greater than or equal to four.

For example, end portion 3 does not need to include the end surface of nitride semiconductor device 1. End portion 3 is a portion for separating transistor portion 2 from other devices. Another element may be disposed in a region adjacent to transistor portion 2 through end portion 3. Examples of the element include a pn diode which utilizes the pn junction of drift layer 12 and first base layer 14. Nitride semiconductor device 1 may include transistor portion 2, end portion 3, and a pn diode.

The first conductivity type may be the p type, the p⁺ type, and the p⁻ type, and the second conductivity type may be the n type, the n⁺ type, and the n⁻ type.

In the embodiments described above, various changes, replacements, additions, omissions and the like can be performed without departing from the scope of claims or the scope equivalent thereto.

### INDUSTRIAL APPLICABILITY

The present disclosure can be utilized as a nitride semiconductor device in which off characteristics are improved, and can be utilized, for example, as a power device such as a power transistor which is used in a power supply circuit or the like of a consumer device such as a television.

1. A nitride semiconductor device comprising:
a substrate;
a first semiconductor layer of a first conductivity type which is disposed above the substrate;
a second semiconductor layer of a second conductivity type which is disposed above the first semiconductor layer;
a third semiconductor layer which is disposed above the second semiconductor layer;
a first opening which penetrates through the third semiconductor layer and the second semiconductor layer to reach the first semiconductor layer;
a semiconductor multilayer having one portion disposed along an inner surface of the first opening and an other portion disposed above the third semiconductor layer and including a channel region of the first conductivity type;
a fourth semiconductor layer of the second conductivity type which is disposed along an upper surface of the semiconductor multilayer;
a gate electrode which is disposed above the fourth semiconductor layer;
a source electrode which is disposed away from the gate electrode;
a drain electrode which is disposed on a side of a lower surface of the substrate; and
a groove which is provided at an end portion of the nitride semiconductor device and penetrates through the second semiconductor layer to reach the first semiconductor layer,
wherein a distance between a bottom of the first opening and the substrate is shorter than a distance between a bottom of the groove and the substrate.

2. The nitride semiconductor device according to claim 1,
wherein a distance between a bottom of the fourth semiconductor layer in the first opening and the substrate is shorter than the distance between the bottom of the groove and the substrate.

3. The nitride semiconductor device according to claim 1, further comprising:
a second opening which is provided away from the gate electrode and penetrates through the semiconductor multilayer and the third semiconductor layer to reach the second semiconductor layer,
wherein the source electrode is provided along an inner surface of the second opening.

4. The nitride semiconductor device according to claim 1,
wherein the first semiconductor layer includes a plurality of layers each of which has a different impurity concentration, and
the bottom of the first opening is located in an nth layer from an uppermost layer among the plurality of layers where n is a natural number greater than or equal to two.

5. The nitride semiconductor device according to claim 4,
wherein the bottom of the groove is located in a layer above the nth layer.

6. The nitride semiconductor device according to claim 4,
wherein the plurality of layers are two layers.

7. The nitride semiconductor device according to claim 4,
wherein the plurality of layers are three layers.

8. The nitride semiconductor device according to claim 4,
wherein the nth layer has a highest impurity concentration among the plurality of layers.

9. The nitride semiconductor device according to claim 4,
wherein the uppermost layer among the plurality of layers has a lower impurity concentration of the first conductivity type than the nth layer.

10. The nitride semiconductor device according to claim 9,
wherein the bottom of the groove is located in the uppermost layer.

11. The nitride semiconductor device according to claim 9,
wherein the bottom of the groove is located in the nth layer.

12. The nitride semiconductor device according to claim 9,
wherein the uppermost layer includes C or Fe.

13. The nitride semiconductor device according to claim 1, further comprising:
an insulating film which is provided along an inner surface of the groove; and
a field plate which is provided above the insulating film to overhang the groove.

14. The nitride semiconductor device according to claim 13,
wherein the field plate is electrically connected to the source electrode.

15. The nitride semiconductor device according to claim 1,
wherein a smaller angle of angles formed by a side wall of the groove and a plane parallel to a main surface of the substrate is less than 90°.

16. The nitride semiconductor device according to claim 1,
wherein the groove is provided in a ring shape in plan view to collectively surround the first opening, the semiconductor multilayer, the fourth semiconductor layer, the gate electrode, and the source electrode, and
the first semiconductor layer includes a high resistance region which is provided in a ring shape along the bottom of the groove and into which an impurity is introduced.

17. The nitride semiconductor device according to claim 16,
wherein the impurity included in the high resistance region is Mg, B, or Fe.

18. The nitride semiconductor device according to claim 16,
wherein the high resistance region includes an end surface of the nitride semiconductor device.
